(19) United States
(12) Patent Application Publication
(10) Pub. No.: US 2018/0323407 A1
(43) Pub. Date: Nov. 8, 2018

(54) ORGANIC LIGHT EMITTING DEVICE AND A METHOD OF FABRICATING THEREOF

(71) Applicant: SHENZHEN CHINA STAR OPTOELECTRONICS TECHNOLOGY CO., LTD., Shenzhen, Guangdong (CN)

(72) Inventor: Zhixiong JIANG, Shenzhen, Guangdong (CN)

(73) Assignee: Shenzhen China Star Optoelectronics Technology Co., Ltd., Shenzhen, Guangdong (CN)

(21) Appl. No.: 15/541,545

(22) PCT Filed: Jun. 15, 2017
(86) PCT No.: PCT/CN2017/088345

§ 371 Date: Jul. 5, 2017

(30) Foreign Application Priority Data
May 2, 2017 (CN) 201710300987.2

(51) Int. Cl. H01L 51/56; H01L 51/52; H01L 51/50; H01L 27/32; H01L 51/00

(52) U.S. Cl. CPC H01L 51/56; H01L 51/5206; H01L 51/5221; H01L 51/0032; H01L 51/5072; H01L 27/3244; H01L 51/5056

(57) ABSTRACT

The present application discloses an organic light emitting device and a method of fabricating thereof, the method of fabricating including the steps: providing a substrate; disposing an anode layer on the substrate; forming a hole injection layer on the anode layer by a first solution; forming an emitting material layer on the hole injection layer by a second solution, wherein the hole injection layer is insoluble in the second solution; forming an electron transport layer on the emitting material layer by a third solution, wherein the emitting material layer is insoluble in the third solution; forming a cathode layer on the electron transport layer. Therefore, present application is capable of fabricating a fine device structure.

### FIELD OF THE INVENTION

The present application relates to a display technology field, and more particularly to an organic light emitting device and a method of fabricating thereof.

### BACKGROUND OF THE INVENTION

Organic light-emitting diodes, OLEDs and liquid crystal displays, LCD have different types of principle for emitting light. The OLED display technology has the advantages of self-luminous, wide viewing angle, almost infinite high contrast, low power consumption, high response speed and so on. Therefore, the organic light-emitting diode has been widely used.

The OLED can be divided into two types according to its light-emitting materials: small molecule OLED and polymer OLED. The difference between the small molecule OLED and the polymer OLED is mainly shown in the different preparation process of the devices: the small molecule device mainly adopts the vacuum thermal evaporation process, the polymer device adopts the spin coating or the spray printing process, namely the solution process technology. In the conventional technology, the solution process type organic light emitting diode, OLED is difficult to realize the preparation of the multilayer device due to the similar solvent systems. Usually, when fabricating the upper functional layer, the lower functional layer is easily dissolved, resulting in hard to fabricate fine device structure in the solution process type device.

### SUMMARY OF THE INVENTION

The technical problem mainly solved by the present application is to provide an organic light emitting device and a method of fabricating the same to be capable of fabricating a fine device structure.

In order to solve the technical problems mentioned above, a technical aspect of the present application is to provide a method for fabricating an organic light emitting device, including: providing a substrate;

disposing an anode layer and an auxiliary electrode on the substrate, wherein the anode layer has a high work function and a light transmittance property;

forming a hole injection layer on the anode layer by a first solution;

forming an emitting material layer on the hole injection layer by a second solution, wherein the hole injection layer is insoluble in the second solution;

forming an electron transport layer on the emitting material layer by a third solution, wherein the emitting material layer is insoluble in the third solution; and

forming a cathode layer on the electron transport layer, wherein the cathode layer is formed by metals with a low work function, or a composite metal.

In order to solve the technical problems mentioned above, another technical aspect of the present application is to provide a method for fabricating an organic light emitting device, including:

providing a substrate;

disposing an anode layer on the substrate;

forming a hole injection layer on the anode layer by a first solution;

forming an emitting material layer on the hole injection layer by a second solution, wherein the hole injection layer is insoluble in the second solution;

forming an electron transport layer on the emitting material layer by a third solution, wherein the emitting material layer is insoluble in the third solution; and

forming a cathode layer on the electron transport layer.

In order to solve the technical problems mentioned above, another technical aspect of the present application is to provide an organic light emitting device, including:

a substrate;

an anode layer disposed on the substrate;

a hole injection layer disposed on the anode layer, wherein the hole injection layer is formed by a first solution;

an emitting material layer disposed on the hole injection layer, wherein the emitting material layer is formed by a second solution, the hole injection layer is insoluble in the second solution;

an electron transport layer disposed on the emitting material layer, wherein the electron transport layer is formed by the third solution, the emitting material layer is insoluble in the third solution; and

a cathode layer disposed on the electron transport layer.

The advantages of the present application is: compared to the conventional technology, the present application provides an organic light emitting device and a method for fabricating the same, the method includes the following steps: firstly, providing a substrate, and then providing an anode layer on the substrate, and then, forming a hole injection layer on the anode layer by a first solution; forming an emitting material layer on the hole injection layer by a second solution, wherein the hole injection layer is insoluble in the second solution; forming an electron transport layer on the emitting material layer by a third solution, wherein the emitting material layer is insoluble in the third solution; and finally forming a cathode layer on the electron transport layer. Therefore, in the present application, the solution used to form the upper layer structure does not dissolve the lower layer structure, whereby the structure of each layer is not destroyed, and can be intact maintained, so as to be able to fabricate fine device structure.

### BRIEF DESCRIPTION OF THE DRAWINGS

In order to more clearly illustrate the embodiments of the present application or prior art, the following FIG.s will be described in the embodiments are briefly introduced. It is obvious that the drawings are merely some embodiments of the present application, those of ordinary skill in this field can obtain other FIG.s according to these FIG.s without paying the premise.

FIG. 1 is a schematic flow diagram of a method of fabricating an organic light emitting device according to an embodiment of the present application;

FIG. 2 is a schematic flow diagram of an organic light emitting device corresponding to the fabricating method shown in FIG. 1;

FIG. 3 is a zero-generation p-πconjugated dendrimers organic material, usually referred to as GO;

FIG. 4 is a schematic flow diagram of another organic light emitting device corresponding to the fabricating method shown in FIG. 1;

FIG. 5 is a schematic flow diagram of another organic light emitting device corresponding to the fabricating method shown in FIG. 1;

FIG. 6 is a schematic flow diagram of another organic light emitting device corresponding to the fabricating method shown in FIG. 1;

FIG. 7 is a schematic flow diagram of another organic light emitting device corresponding to the fabricating method shown in FIG. 1;

FIG. 8 is a schematic structural view of the organic light emitting device according to an embodiment of the present application;

FIG. 9 is a schematic structural view of another organic light emitting device according to an embodiment of the present application;

FIG. 10 is a schematic structural view of another organic light emitting device according to an embodiment of the present application;

FIG. 11 is a schematic structural view of another organic light emitting device according to an embodiment of the present application; and

FIG. 12 is a schematic structural view of another organic light emitting device according to an embodiment of the present application.

### DETAILED DESCRIPTION OF PREFERRED EMBODIMENTS

Embodiments of the present application are described in detail with the technical matters, structural features, achieved objects, and effects with reference to the accompanying drawings as follows. It is clear that the described embodiments are part of embodiments of the present application, but not all embodiments. Based on the embodiments of the present application, all other embodiments to those of ordinary skill in the premise of no creative efforts acquired should be considered within the scope of protection of the present application.

Specifically, the terminologies in the embodiments of the present application are merely for describing the purpose of the certain embodiment, but not to limit the invention. Embodiments and the claims be implemented in the present application requires the use of the singular form of the book “an”, “the” and “the” are intend to include most forms unless the context clearly dictates otherwise. It should also be understood that the terminology used herein that “and/or” means and includes any or all possible combinations of one or more of the associated listed items.

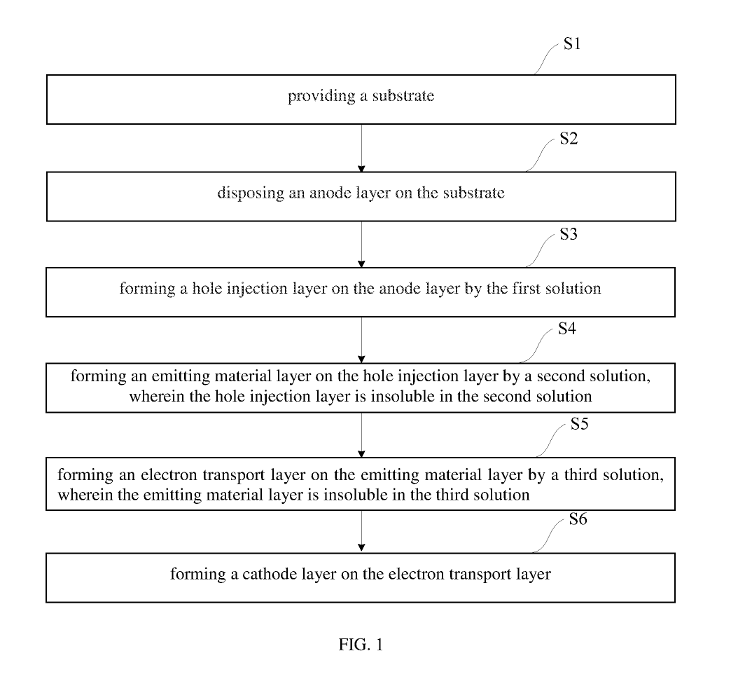

Referring to FIG. 1, FIG. 1 is a schematic flow diagram of a method of fabricating an organic light emitting device according to an embodiment of the present application. As shown in FIG. 1, the method of fabricating of the present embodiment includes the following steps:

Step S1: providing a substrate 101.

The substrate of this step is processed by cleaning, drying and the like to obtain a clean substrate.

The material of the substrate can be glass.

Step S2: disposing an anode layer 102 on the substrate 101. Specifically, the anode layer 102 is disposed by vapor deposition.

In this step, the material used in the anode layer 102 is having a high work function and a light transmittance. An indium tin oxide, ITO transparent conductive film having a high work function of 4.5 eV to 5.3 eV, and having a stable and translucent property and is widely used for the anode layer 102.

In other embodiments, an auxiliary electrode can be added on the anode layer 102. Since the OLED is a current driving device, when the external circuit is too long or too thin, it causes a severe voltage gradient with the external circuit, and it makes the voltage of the OLED device dropping and resulting in the reduce of the panel luminous intensity. Due to the resistance of the ITO is too large (10 ohm/square), it is easy to cause unnecessary external power consumption. By adding an auxiliary electrode can reduce the voltage gradient and it becomes a shortcut to increase the luminous efficiency and reduce the drive voltage. Chromium, Cr metal is the most commonly used as material for auxiliary electrode; it has the advantages of good stability to the environmental factors and has a greater selectivity to the etching solution and so on. However, when the thickness of the layer is 100 nm, its resistance is 2 ohm/square, it is still too larger in some applications. Therefore, aluminum, Al metal with a lower resistance (0.2 ohm/square) at the same thickness is became another preferred choice for the auxiliary electrode. However, the high activity of the aluminum metal also makes it has a reliable problem. Therefore, in order to enhance the stability of the auxiliary electrode as well, a multi-laminated structure of the auxiliary metal can be used as the auxiliary electrode, for example, Cr/Al/Cr, or molybdenum, Mo/Al/Mo.

Step S3: forming a hole injection layer, HIL 103 on the anode layer 102 by the first solution. In this step, when the hole is injected into the HIL from the ITO layer, the oversized potential difference will generate Schottky barrier, so that the hole is not easy to be injected, so that how to reduce the potential difference of the ITO/HIL interface is became the focus of the pre-treatment of the ITO. Therefore, in the present embodiment, the step S2 described above, the saturation of the oxygen atoms in the ITO is further increased by the O₂-Plasma method to achieve the purpose of increasing the work function value. The work function value of ITO treatment by O₂-Plasma can be raised from the original 4.8 eV and upgrade to 5.2 eV, and is very close to the work function of the HIL.

Step S4: forming an emitting material layer, EML 104 on the hole injection layer 103 by a second solution, wherein the hole injection layer 103 is insoluble in the second solution. That is, the solvent of the first solution and the solvent system of the second solution are not similar.

Step S5: forming an electron transport layer, ETL 105 on the emitting material layer 104 by a third solution, wherein the emitting material layer is insoluble in the third solution. That is, the solvent of the third solution and the solvent system of the second solution are not similar.

Step S6: forming a cathode layer 106 on the electron transport layer 105. Specifically, the cathode layer 106 is formed by vapor deposition method.

In order to increase the luminous efficiency of the organic light emitting device, the cathode layer 106 of this step can formed by selecting metals of silver, Ag, aluminum, Al, calcium, Ca, indium, In, lithium, Li and magnesium, Mg, or a composite metal with low work function, for example, magnesium-silver, Mg—Ag.

Therefore, by the solvent system of the solutions used in the adjacent two-layer structure in the present embodiment is not close to each other, so that the solution used to form the upper layer structure does not dissolve the lower layer structure, whereby the structure of each layer is not destroyed, and can be intact maintained, so as to be able to fabricate fine device structure.

The specific embodiment of the above steps will be described in detail based on the specific materials used in the different structural layers of the organic light emitting device.

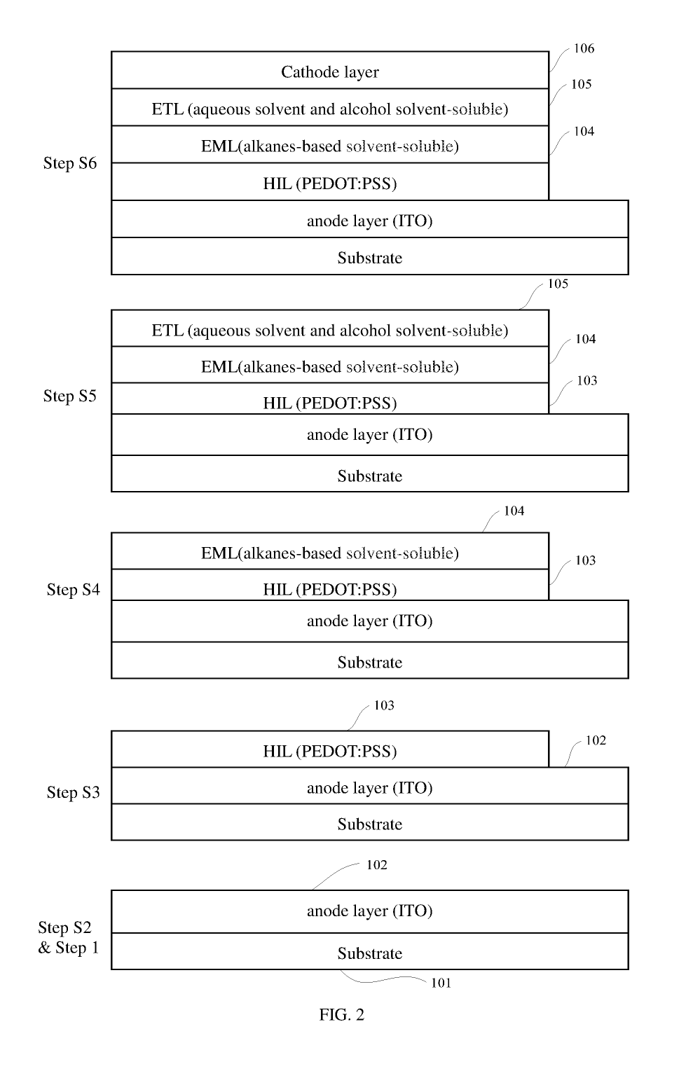

Referring to FIG. 2, the material of the hole injection layer 103 is PEDOT: PSS material, and the material of the emitting material layer 104 is a first non-polar type solvent-soluble organic material, and the material of the electron transport layer 105 is a polar type solvent-soluble organic material.

Wherein, the first non-polar type solvent includes an alkanes-based solvent and the like, and the polar type solvent includes an aqueous solvent and an alcohol solvent. Alcohol solvents include methanol, ethanol, and the like.

Wherein, PEDOT: PSS is an aqueous solution with macromolecular polymer, having high conductivity, according to the different composition, the aqueous solution with different conductivity can be obtained. The compound is composed of two substances of PEDOT and PSS. PEDOT is a polymer of EDOT (3,4-ethylenedioxythiophene monomer), and PSS is polystyrene sulfonate. These two substances together will greatly improve the solubility of PEDOT, the conductive aqueous solution is mainly used in the hole injection layer, HIL of the organic light emitting diodes, organic solar cells, organic thin film transistors and super capacitors. That is the PEDOT: PSS is insoluble in general organic solvents.

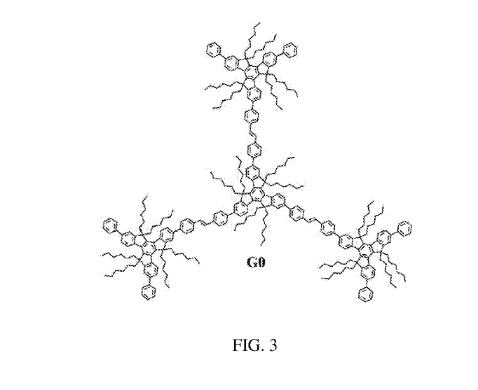

The organic material can be dissolved by the alkane-based solvent, such as the material of the emitting material layer 104 of this embodiment has a long alkane branch, as shown in FIG. 3, which is a zero-generation p-πconjugated dendrimers organic material, usually referred to as G0, the monomer is a stilbenoid-based compounds, and the branched is a long alkyl chain.

The above-mentioned alkane-based solvent-soluble organic material can be dissolved in the second non-polar type solvent and it can be dissolved by an alkane-based solvent such as C₈H₁₈ and C₁₂H₂₆. Wherein, the second non-polar type solvent includes a benzene solvent, a xylene solvent, a chlorobenzene solvent and a chloroform solvent.

Specifically, the step S3 described above is: the PEDOT: PSS solution is first formed by dissolving the PEDOT: PSS material by water as a solvent, and then the PEDOT: PSS solution is disposed on the anode layer 102 to form the hole injection layer 103. Specifically, the PEDOT:

PSS solution was dropped on the anode layer 102 by spin coating method, and then the PEDOT:

PSS solution was uniformly spread by high-speed rotation. Finally, the PEDOT: PSS solution was cured by drying or the like to obtain the hole injection layer 103.

It is to be understood that the process of forming the above-described hole injection layer 103 can be carried out by using the specific process for forming different structural layers by different solutions according to the present application.

Specifically, the step S4 described above is: first, the material of the emitting material layer is dissolved by the alkane-based solvent to form an alkane-based solution, and then the alkane-based solution is disposed on the hole-injecting layer 103 to form the emitting material layer 104.

In other embodiments, the solvent of the emitting material layer 104 can also be a second non-polar type solvent such as the benzene solvent, the xylene solvent, the chlorobenzene solvent or the chloroform solvent.

Specifically, the step S5 described above is: first, the material of the electron transport layer is dissolved by the aqueous solvent or the alcohol solvent to form the aqueous solution or the alcohol solution, and then the aqueous solution or the alcohol solution is disposed on the emitting material layer 104 to form the electron transport layer.

Wherein, the specific steps S1, S2, and S6 are as described above, and will not be described again.

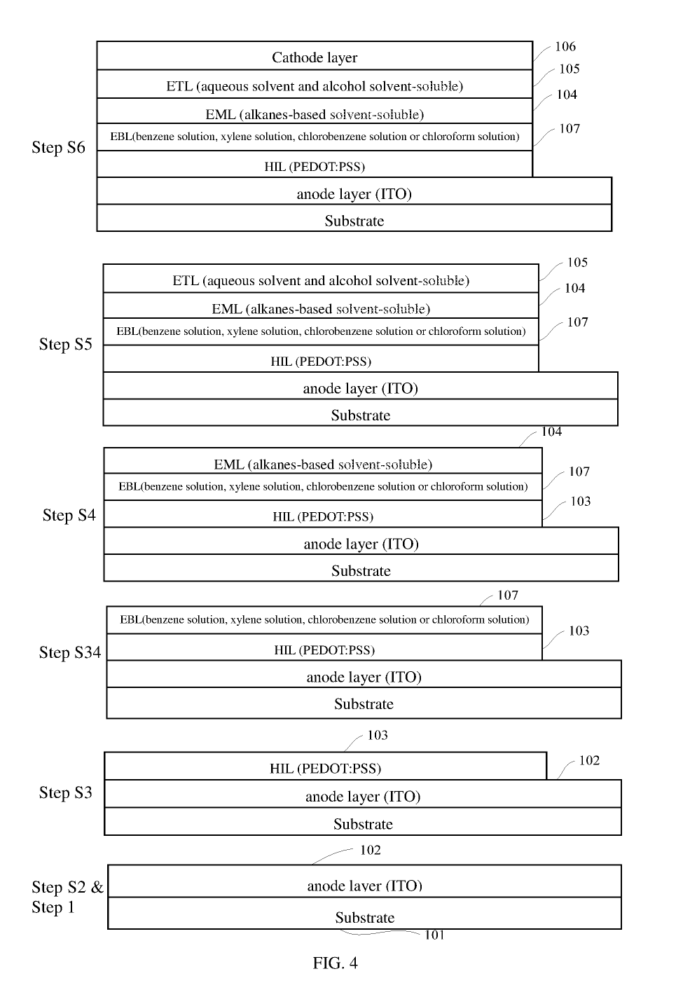

Referring to FIG. 4, the organic light emitting device illustrated in FIG. 4 further includes an electron blocking layer, EBL 107, and the material of the electron blocking layer 107 is a second non-polar type solvent-soluble organic material. Wherein, the second non-polar type solvent includes the benzene solvent, the xylene solvent, the chlorobenzene solvent and the chloroform solvent.

Thus, after the step S3, the material of the electron blocking layer is further dissolved by the benzene solvent, the xylene solvent, the chlorobenzene solvent or the chloroform solvent to form a benzene solution, a xylene solution, a chlorobenzene solution or a chloroform solution. Then, the benzene solution, the xylene solution, the chlorobenzene solution or the chloroform solution is disposed on the hole injection layer 103 to form the electron blocking layer 107.

The above mentioned process can be performed between steps S3 and S4, and defined as S34.

Wherein, the specific steps S1-S6 are as described above, and will not be described again.

In the present embodiment, since the electron blocking layer 107 is provided and the solvent of the electron blocking layer 107 is the second non-polar type solvent, and the solvent system is different from the alkane-base solvent for the emitting material layer 104 on the upper layer of the electron blocking layer 107. Thus, when the emitting material layer 104 is fabricated in step S4, the alkane-based solution used therein does not corrode and damages the electron blocking layer 107 to ensure that the electron blocking layer 107 is intact. Thereby improving the hole transport performance of the organic light emitting device.

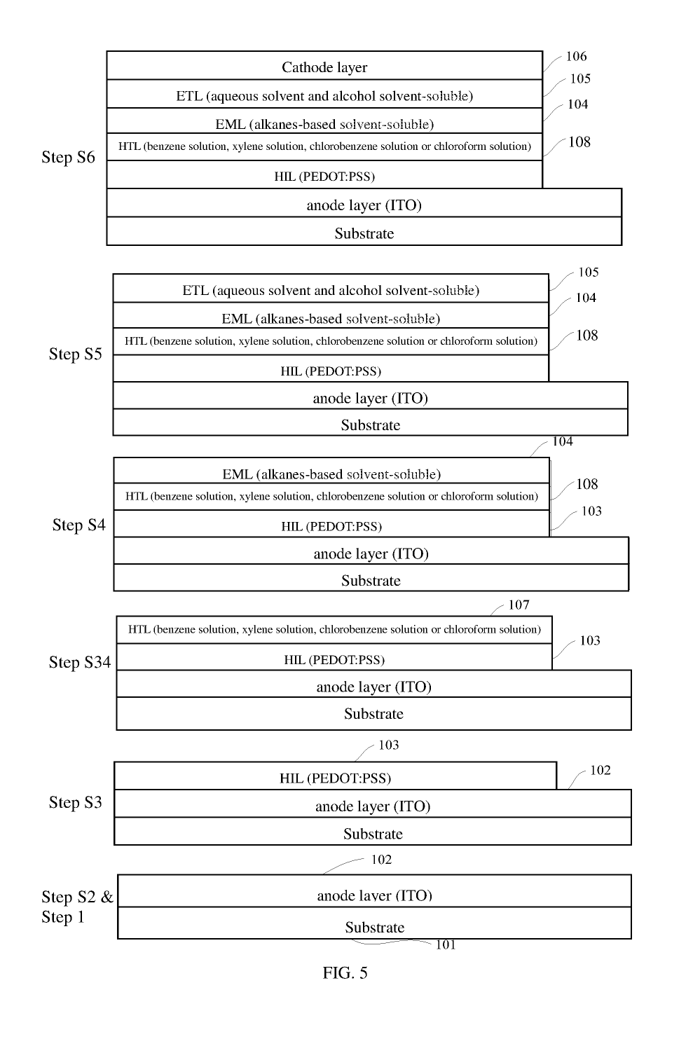

Referring to FIG. 5, the organic light emitting device of the present embodiment further includes a hole transport layer 108, HTL, and the material of the hole transport layer 108 is a second non-polar type solvent-soluble organic material, wherein the second non-polar type solvent includes the benzene solvent, the xylene solvent, the chlorobenzene solvent and the chloroform solvent.

After the step S3 described above, the material of the hole transport layer is further dissolved by the benzene solvent, the xylene solvent, the chlorobenzene solvent or the chloroform solvent to form the benzene solution, the xylene solution, the chlorobenzene solution or the chloroform solution, and then, he benzene solution, the xylene solution, the chlorobenzene solution or the chloroform solution is disposed on the hole injection layer 103 to form the hole transport layer 108.

Specifically, the hole injection layer 108 can be formed between step S3 and step S4, and is defined as step S34.

Wherein, the specific steps S1-S6 are as described above, and will not be described again.

The fabricating method describes above is the alkane-base material of organic material used in the emitting material layer, and the following describes the fabricating method when the organic material of the alkane is used in other structural layers of the organic light-emitting device.

First referring to FIG. 6, the organic light emitting device of the present embodiment further includes a hole blocking layer, HBL 109, the material of which is a first non-polar type solvent-soluble organic material. The material of the hole injection layer is PEDOT: PSS material. The material of the emitting material layer is a second non-polar type solvent-soluble organic material. The material of the electron transport layer is a polar type solvent-soluble organic material.

Wherein the first non-polar type solvent includes an alkane-based solvent and the second non-polar type solvent includes the benzene solvent, the xylene solvent, the chlorobenzene solvent and the chloroform solvent, and the polar type solvent includes the aqueous solvent or the alcohol solvent. That is, the organic material of the alkane of this embodiment is used in the hole blocking layer.

Specifically, the step S3 described above is: the PEDOT: PSS solution is first formed by dissolving the PEDOT: PSS material by water as a solvent, and then the PEDOT: PSS solution is disposed on the anode layer 102 to form the hole injection layer 103.

Specifically, the step S4 described above is: the material of the emitting material layer is dissolved in the benzene solvent, the xylene solvent, the chlorobenzene solvent and the chloroform solvent to form the benzene solution, the dimethyl solution, the chlorobenzene solution and the chloroform solution. Then the benzene solution, the dimethyl solution, the chlorobenzene solution and the chloroform solution is disposed on the hole injection layer 103 to form the emitting material layer.

After the step S4, the alkane-based solution is further formed by dissolving the material of the hole blocking layer through the alkane-based solvent, and then the alkane-based solution is disposed on the emitting material layer 104 to form the hole blocking layer 109. This step can be performed between steps S4 and S5 specifically to form the hole blocking layer 109, and therefore, the step is defined as S45.

Specifically, the step S4 described above is: the aqueous solution or the alcohol solution is first formed by dissolving the material of the electron transport layer by the aqueous solvent or the alcohol solvent, and then the aqueous solution or the alcohol solution is provided on the hole blocking layer to form the electron transport layer 105.

Wherein, steps S1, S2, and S6 are as described above, and will not be described again.

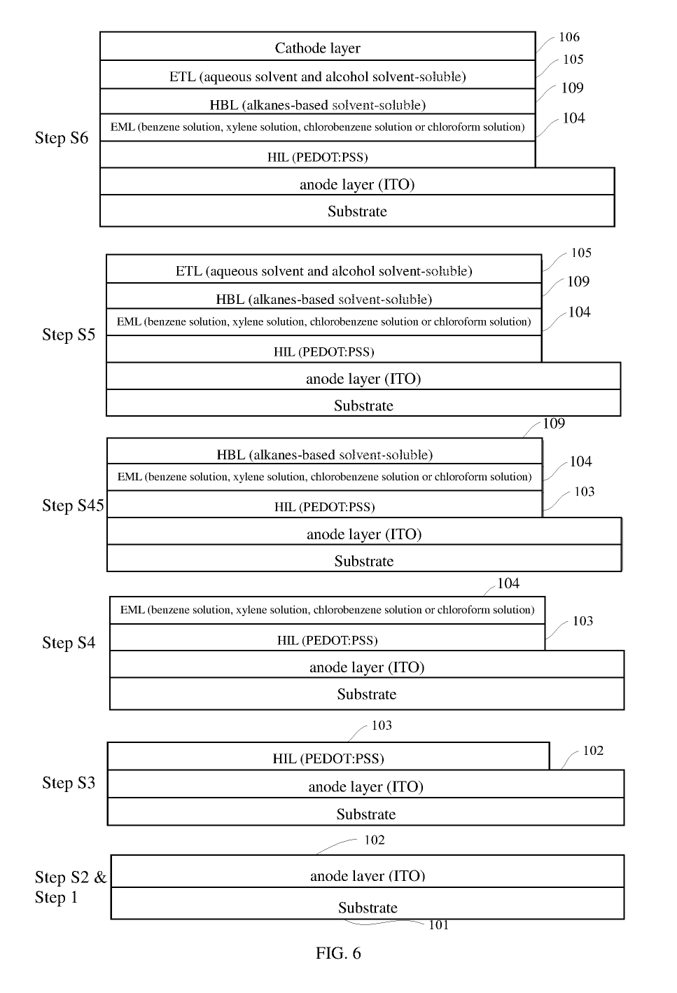

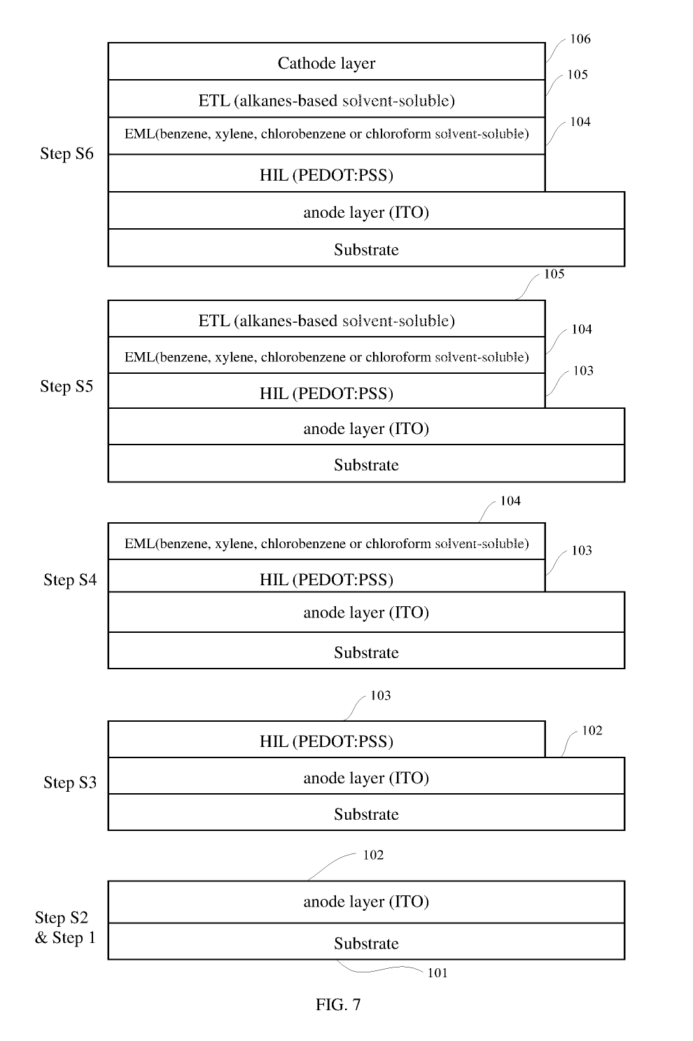

Referring to FIG. 7, the material of the hole injection layer of this embodiment is a PEDOT: PSS material, the material of the electron transport layer is a first non-polar type solvent-soluble organic material, and the material of the emitting material layer is a second non-polar type

Solvent-soluble organic material, wherein the first non-polar type solvent includes the alkane-based solvent and the second non-polar type solvent includes the benzene solvent, the xylene solvent, the chlorobenzene solvent and the chloroform solvent. That is, the organic material of the alkane of the present embodiment is used in the electron transport layer.

Specifically, the step S3 described above is: the PEDOT: PSS solution is first formed by dissolving the PEDOT: PSS material by water as a solvent, and then the PEDOT: PSS solution is disposed on the anode layer 102 to form the hole injection layer 103.

Specifically, the step S4 described above is: the material of the emitting material layer is dissolved in the benzene solvent, the xylene solvent, the chlorobenzene solvent and the chloroform solvent to form the benzene solution, the dimethyl solution, the chlorobenzene solution and the chloroform solution. Then the benzene solution, the dimethyl solution, the chlorobenzene solution and the chloroform solution is disposed on the hole injection layer 103 to form the emitting material layer.

Specifically, the step S5 described above is: the alkane-based solution is formed by dissolving the material of the electron transport layer by the alkane-based solvent, and then the alkane-based solution is disposed on the emitting material layer 104 to form the electron transport layer 105.

Wherein, steps S1, S2, and S6 are as described above, and will not be described again.

The present application also provides an organic light emitting device which is obtained according to the fabricating method described above. The structure of the organic light emitting device is as follows:

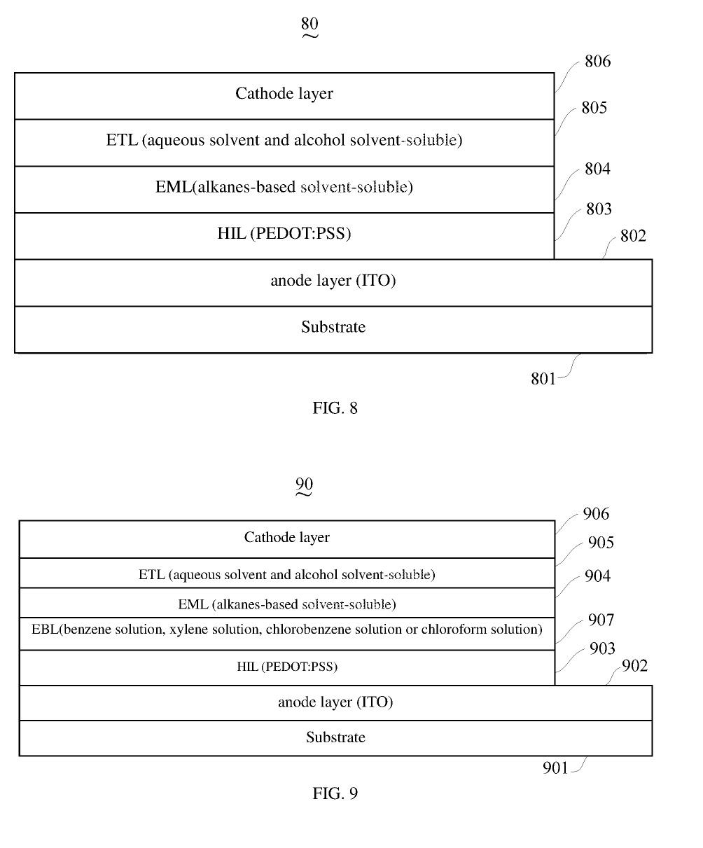

Referring to FIG. 8, the organic light emitting device 80 of the present embodiment includes a substrate 801, an anode layer 802, a hole injection layer 803, a emitting material layer 804, an electron transport layer 805, and a cathode layer 806.

Wherein, the anode layer 802 is disposed on the substrate 801.

Wherein, the materials used in the anode layer 802 are as described above and will not be described here.

In other embodiments, the auxiliary electrode can be added on the anode layer 802, and the specific arrangement of the auxiliary electrode is as described above and will not be described further herein.

The hole injection layer 803 is disposed on the anode layer 802, the hole injection layer 803 is formed by the first solution.

The emitting material layer 804 is disposed on the hole injection layer 803, wherein the emitting material layer 804 is formed by the second solution, and the hole injection layer 803 is insoluble in the second solution. That is, the solvent system of the first solution and the solvent system of the second solution are not similar.

The electron transport layer 805 is disposed on the emitting material layer 804, wherein the electron transport layer 805 is formed by the third solution, and the emitting material layer 804 is insoluble in the third solution. That is, the solvent system of the third solution and the solvent system of the second solution are not similar.

The cathode layer 806 is provided on the electron transport layer 805.

In order to increase the luminous efficiency of the organic light emitting device, the cathode layer 806 of this step can formed by selecting metals of silver, Ag, aluminum, Al, calcium, Ca, indium, In, lithium, Li and magnesium, Mg, or a composite metal with low work function, for example, magnesium-silver, Mg—Ag.

In the present embodiment, the material of the hole injection layer 803 is a PEDOT: PSS material, the material of the emitting material layer 804 is the first non-polar type solvent-soluble organic material, and the material of the electron transport layer 805 is a polar type solvent-soluble organic material.

Wherein, PEDOT: PSS is an aqueous solution with macromolecular polymer, having high conductivity, according to the different composition, the aqueous solution with different conductivity can be obtained. The compound is composed of two substances of PEDOT and PSS. PEDOT is a polymer of EDOT (3,4-ethylenedioxythiophene monomer), and PSS is polystyrene sulfonate. These two substances together will greatly improve the solubility of PEDOT, the conductive aqueous solution is mainly used in the hole injection layer, HIL of the organic light emitting diodes, organic solar cells, organic thin film transistors and super capacitors. That is the PEDOT: PSS is insoluble in general organic solvents.

The first type of the non-polar type solvents includes alkane-based solvents, the polar type solvents includes aqueous solvents and alcohol solvents. Alcohol solvents include methanol and ethanol.

Wherein, the alkane-based solvent-soluble organic material is as described above and shown in FIG. 3, and will not be described here.

The above-mentioned alkane-based solvent-soluble organic material can be dissolved in a second non-polar type solvent and can be dissolved by an alkane-based solvent such as C₈H₁₈ and C₁₂14₂₆.

In other embodiments, the solvent of the emitting material layer 804 can also be a second non-polar type solvent such as the benzene solvent, the xylene solvent, the chlorobenzene solvent or the chloroform solvent.

Referring to FIG. 9, the organic light emitting device 90 shown in FIG. 9 includes a substrate 901, an anode layer 902, a hole injection layer 903, a emitting material layer 904, an electron transport layer 905, and a cathode layer 906.

However, the difference of the organic light emitting device 90 shown in FIG. 9 and the organic light emitting device 80 shown in FIG. 8 is the organic light emitting device 90 shown in FIG. 9 further includes an electron blocking layer 907 disposed between the hole injection layer 903 and the emitting material layer 904.

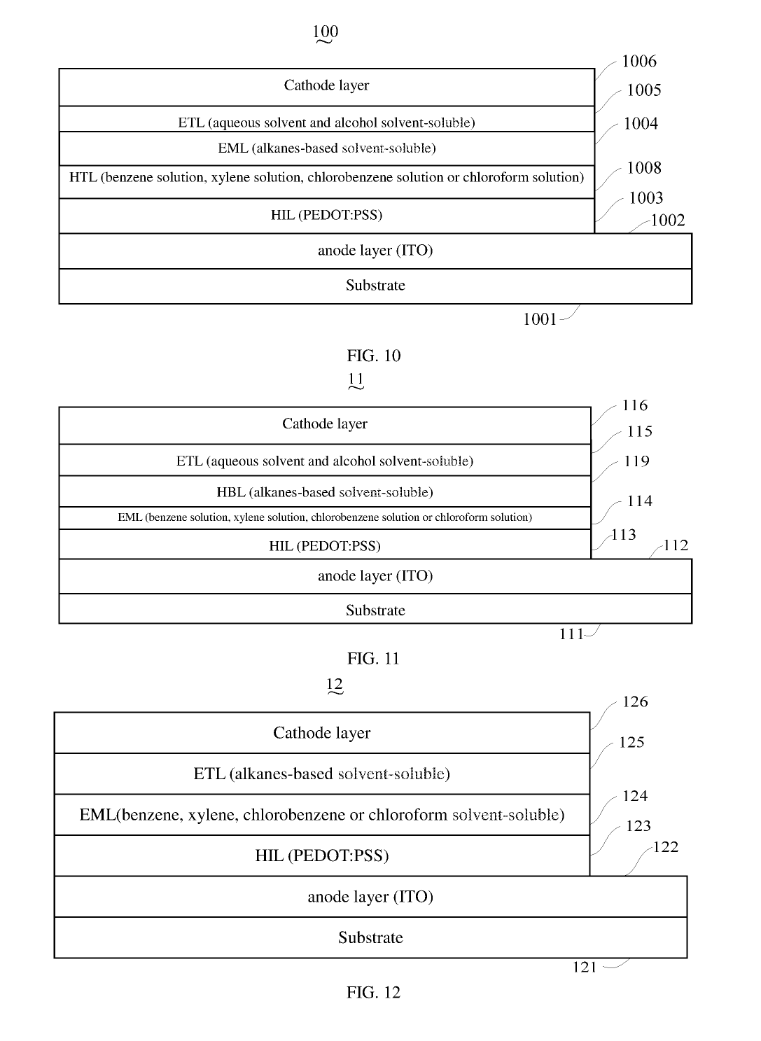

In the present embodiment, the material of the electron blocking layer 907 is a second non-polar type solvent-soluble organic material. Wherein, the second non-polar type solvent includes the benzene solvent, the xylene solvent, the chlorobenzene solvent and the chloroform solvent. Referring to FIG. 10, the organic light emitting device 100 shown in FIG. 10 still includes a substrate 1001, an anode layer 1002, a hole injection layer 1003, a emitting material layer 1004, an electron transport layer 1005, and a cathode layer 1006.

However, the difference of the organic light emitting device 100 shown in FIG. 10 and the organic light emitting device 80 shown in FIG. 8 is the organic light emitting device 100 shown in FIG. 10 further includes a hole transport layer 1008 disposed between the hole injection layer 1003 and the emitting material layer 1004.

In the present embodiment, the material of the hole transport layer 1008 is a second non-polar type solvent-soluble organic material. Wherein, the second non-polar type solvent includes the benzene solvent, the xylene solvent, the chlorobenzene solvent and the chloroform solvent.

Referring to FIG. 11, the organic light emitting device 11 shown in FIG. 11 still includes a substrate 111, an anode layer 112, a hole injection layer 113, a emitting material layer 114, an electron transport layer 115, and a cathode layer 116.

However, the difference of the organic light emitting device 11 shown in FIG. 11 and the organic light emitting device 80 shown in FIG. 8 is the organic light emitting device 11 shown in FIG. 11 further includes a hole blocking layer 119, its material is a first non-polar type solvent-soluble organic materials. The material of the emitting material layer 114 is a second non-polar type solvent-soluble organic material, and the material of the electron transport layer 115 is a polar type solvent-soluble organic material.

Wherein, the first non-polar type solvent, the second non-polar type solvent and the polar solvent are as described above, and will not be described here.

Referring to FIG. 12, the organic light emitting device 12 shown in FIG. 12 still includes a substrate 121, an anode layer 122, a hole injection layer 123, a emitting material layer 124, an electron transport layer 125, and a cathode layer 126. And the material of the hole injection layer 123 is a PEDOT: PSS material.

However, the difference of the organic light emitting device 12 shown in FIG. 12 and the organic light emitting device 80 shown in FIG. 8 is the material of the electron transport layer 125 of the organic light emitting device 12 as shown in FIG. 12 is a first non-polar type solvent-soluble organic material, and the material of the emitting material layer 124 is a second non-polar type solvent-soluble organic material. Wherein, the first non-polar type solvent and the second non-polar type solvent are as described above, and will not be described here.

In view of the above, the solvent system of the solutions used in the adjacent two-layer structure in the present embodiment is not close to each other, so that the solution used to form the upper layer structure does not dissolve the lower layer structure, whereby the structure of each layer is not destroyed, and can be intact maintained, so as to be able to fabricate fine device structure. So that the energy level between each of the functional layers can be more reasonable matched, the driving voltage can be reduced, the life of organic light-emitting devices can be increased; exciton utilization can be improved, and the efficiency of organic light-emitting devices can be increased.

The fabricating method of the present application can not only be applied to the organic light emitting devices, such as OLEDs, but also be applied to the organic solar devices, OSCs. Above are embodiments of the present application, which does not limit the scope of the present application. Any modifications, equivalent replacements or improvements within the spirit and principles of the embodiment described above should be covered by the protected scope of the invention.

What is claimed is:

1. A method of fabricating of an organic light emitting device comprising the following steps:
providing a substrate;
disposing an anode layer and an auxiliary electrode on the substrate, wherein the anode layer has a high work function and a light transmittance property;
forming a hole injection layer on the anode layer by a first solution;
forming an emitting material layer on the hole injection layer by a second solution, wherein the hole injection layer is insoluble in the second solution;
forming an electron transport layer on the emitting material layer by a third solution, wherein the emitting material layer is insoluble in the third solution; and
forming a cathode layer on the electron transport layer, wherein the cathode layer is formed by metals with a low work function, or a composite metal.

2. The method of fabricating of the organic light emitting device according to claim 1, wherein the material of the hole injection layer is PEDOT: PSS material, and the material of the emitting material layer is a first non-polar type solvent-soluble organic material, and the material of the electron transport layer is a polar type solvent-soluble organic material;
wherein, the first non-polar type solvent comprising an alkanes-based solvent, and the polar type solvent comprising an aqueous solvent and an alcohol solvent;
the step of forming the hole injection layer on the anode layer by the first solution comprising:
forming the PEDOT: PSS solution by dissolving the PEDOT: PSS material by aqueous solvent;
disposing the PEDOT: PSS solution on the anode layer to form the hole injection layer;
the step of forming the emitting material layer on the hole injection layer by the second solution comprising:
forming an alkane-based solution by dissolving the material of the emitting material layer by the alkane-based solvent;
disposing the alkane-based solution on the hole-injecting layer to form the emitting material layer;
the step of forming the electron transport layer on the emitting material layer by the third solution comprising:
forming an aqueous solution or an alcohol solution by dissolving the material of the electron transport layer by the aqueous solvent or the alcohol solvent; and
disposing the aqueous solution or the alcohol solution on the emitting material layer to form the electron transport layer.

3. The method of fabricating of the organic light emitting device according to claim 2, wherein the organic light emitting device further comprising an electron blocking layer, the material of the electron blocking layer is a second non-polar type solvent-soluble organic material, wherein the second non-polar type solvent comprising a benzene solvent, a xylene solvent, a chlorobenzene solvent or a chloroform solvent;
after the step of forming the hole injection layer on the anode layer by the first solution further comprising the step of:
forming a benzene solution, a xylene solution, a chlorobenzene solution or a chloroform solution by dissolving the material of the electron blocking layer by the benzene solvent, the xylene solvent, the chlorobenzene solvent or the chloroform solvent; and
disposing the benzene solution, the xylene solution, the chlorobenzene solution or the chloroform solution on the hole injection layer to form the electron blocking layer.

4. The method of fabricating of the organic light emitting device according to claim 2, wherein the organic light emitting device further comprising a hole transport layer, the material of the hole transport layer is the second non-polar type solvent-soluble organic material, wherein the second non-polar type solvent comprising the benzene solvent, the xylene solvent, the chlorobenzene solvent or the chloroform solvent;
after the step of forming the hole injection layer on the anode layer by the first solution further comprising the step of:
forming the benzene solution, the xylene solution, the chlorobenzene solution or the chloroform solution by dissolving the material of the hole transport layer by the benzene solvent, the xylene solvent, the chlorobenzene solvent or the chloroform solvent; and
disposing the benzene solution, the xylene solution, the chlorobenzene solution or the chloroform solution on the hole injection layer to form the hole transport layer.

5. The method of fabricating of the organic light emitting device according to claim 1, wherein the organic light emitting device further comprising a hole blocking layer, the material of the hole blocking layer is a first non-polar type solvent-soluble organic material; the material of the hole injection layer is PEDOT: PSS material, the material of the emitting material layer is the second non-polar type solvent-soluble organic material, the material of the electron transport layer is the polar type solvent-soluble organic material.;
wherein the first non-polar type solvent comprising an alkane-based solvent, the second non-polar type solvent comprising the benzene solvent, the xylene solvent, the chlorobenzene solvent and the chloroform solvent, the polar type solvent comprising the aqueous solvent or the alcohol solvent;
the step of forming the hole injection layer on the anode layer by the first solution comprising:
forming the PEDOT: PSS solution by dissolving the PEDOT: PSS material by aqueous solvent;
disposing the PEDOT: PSS solution on the anode layer to form the hole injection layer;
the step of forming the emitting material layer on the hole injection layer by the second solution comprising:
forming the benzene solution, the dimethyl solution, the chlorobenzene solution or the chloroform solution by dissolving the material of the emitting material layer in the benzene solvent, the xylene solvent, the chlorobenzene solvent or the chloroform solvent;
disposing the benzene solution, the dimethyl solution, the chlorobenzene solution or the chloroform solution on the hole injection layer to form the emitting material layer;
after the step of forming the emitting material layer on the hole injection layer by the second solution further comprising the step of:
forming the alkane-based solution by dissolving the material of the hole blocking layer in the alkane-based solvent;
disposing the alkane-based solution on the emitting material layer to form the hole blocking layer;
the step of forming the electron transport layer on the emitting material layer by the third solution comprising:
forming the aqueous solution or the alcohol solution by dissolving the material of the electron transport layer by the aqueous solvent or the alcohol solvent; and
disposing the aqueous solution or the alcohol solution the hole blocking layer to form the electron transport layer.

6. The method of fabricating of the organic light emitting device according to claim 1, wherein the material of the hole injection layer is a PEDOT: PSS material, the material of the electron transport layer is the first non-polar type solvent-soluble organic material, and the material of the emitting material layer is the second non-polar type solvent-soluble organic material, wherein the first non-polar type solvent comprising the alkane-based solvent, the second non-polar type solvent comprising the benzene solvent, the xylene solvent, the chlorobenzene solvent and the chloroform solvent;
the step of forming the hole injection layer on the anode layer by the first solution comprising:
forming the PEDOT: PSS solution by dissolving the PEDOT: PSS material by aqueous solvent;
disposing the PEDOT: PSS solution on the anode layer to form the hole injection layer;
the step of forming the emitting material layer on the hole injection layer by the second solution comprising:
forming the benzene solution, the dimethyl solution, the chlorobenzene solution or the chloroform solution by dissolving the material of the emitting material layer in the benzene solvent, the xylene solvent, the chlorobenzene solvent or the chloroform solvent;
disposing the benzene solution, the dimethyl solution, the chlorobenzene solution or the chloroform solution on the hole injection layer to form the emitting material layer;
the step of forming the electron transport layer on the emitting material layer by the third solution comprising:
forming the alkane-based solution by dissolving the material of the electron transport layer by the alkane-based solvent; and
disposing the alkane-based solution the emitting material layer to form the electron transport layer.

7. A method of fabricating of an organic light emitting device comprising the following steps:
providing a substrate;
disposing an anode layer on the substrate;
forming a hole injection layer on the anode layer by a first solution;
forming an emitting material layer on the hole injection layer by a second solution, wherein the hole injection layer is insoluble in the second solution;
forming an electron transport layer on the emitting material layer by a third solution, wherein the emitting material layer is insoluble in the third solution; and
forming a cathode layer on the electron transport layer.

8. The method of fabricating of the organic light emitting device according to claim 7, wherein the material of the hole injection layer is PEDOT: PSS material, and the material of the emitting material layer is a first non-polar type solvent-soluble organic material, and the material of the electron transport layer is a polar type solvent-soluble organic material;
wherein, the first non-polar type solvent comprising an alkanes-based solvent, and the polar type solvent comprising an aqueous solvent and an alcohol solvent;
the step of forming the hole injection layer on the anode layer by the first solution comprising:
forming the PEDOT: PSS solution by dissolving the PEDOT: PSS material by aqueous solvent;
disposing the PEDOT: PSS solution on the anode layer to form the hole injection layer;
the step of forming the emitting material layer on the hole injection layer by the second solution comprising:
forming an alkane-based solution by dissolving the material of the emitting material layer by the alkane-based solvent;
disposing the alkane-based solution on the hole-injecting layer to form the emitting material layer;
the step of forming the electron transport layer on the emitting material layer by the third solution comprising:
forming an aqueous solution or an alcohol solution by dissolving the material of the electron transport layer by the aqueous solvent or the alcohol solvent; and
disposing the aqueous solution or the alcohol solution on the emitting material layer to form the electron transport layer.

9. The method of fabricating of the organic light emitting device according to claim 8, wherein the organic light emitting device further comprising an electron blocking layer, the material of the electron blocking layer is a second non-polar type solvent-soluble organic material, wherein the second non-polar type solvent comprising a benzene solvent, a xylene solvent, a chlorobenzene solvent or a chloroform solvent;
after the step of forming the hole injection layer on the anode layer by the first solution further comprising the step of:
forming a benzene solution, a xylene solution, a chlorobenzene solution or a chloroform solution by dissolving the material of the electron blocking layer by the benzene solvent, the xylene solvent, the chlorobenzene solvent or the chloroform solvent; and
disposing the benzene solution, the xylene solution, the chlorobenzene solution or the chloroform solution on the hole injection layer to form the electron blocking layer.

10. The method of fabricating of the organic light emitting device according to claim 8, wherein the organic light emitting device further comprising a hole transport layer, the material of the hole transport layer is the second non-polar type solvent-soluble organic material, wherein the second non-polar type solvent comprising the benzene solvent, the xylene solvent, the chlorobenzene solvent or the chloroform solvent;
after the step of forming the hole injection layer on the anode layer by the first solution further comprising the step of:
forming the benzene solution, the xylene solution, the chlorobenzene solution or the chloroform solution by dissolving the material of the hole transport layer by the benzene solvent, the xylene solvent, the chlorobenzene solvent or the chloroform solvent; and
disposing the benzene solution, the xylene solution, the chlorobenzene solution or the chloroform solution on the hole injection layer to form the hole transport layer.

11. The method of fabricating of the organic light emitting device according to claim 7, wherein the organic light emitting device further comprising a hole blocking layer, the material of the hole blocking layer is a first non-polar type solvent-soluble organic material; the material of the hole injection layer is PEDOT: PSS material, the material of the emitting material layer is the second non-polar type solvent-soluble organic material, the material of the electron transport layer is the polar type solvent-soluble organic material;
wherein the first non-polar type solvent comprising an alkane-based solvent, the second non-polar type solvent comprising the benzene solvent, the xylene solvent, the chlorobenzene solvent and the chloroform solvent, the polar type solvent comprising the aqueous solvent or the alcohol solvent;
the step of forming the hole injection layer on the anode layer by the first solution comprising:
forming the PEDOT: PSS solution by dissolving the PEDOT: PSS material by aqueous solvent;
disposing the PEDOT: PSS solution on the anode layer to form the hole injection layer;
the step of forming the emitting material layer on the hole injection layer by the second solution comprising:
forming the benzene solution, the dimethyl solution, the chlorobenzene solution or the chloroform solution by dissolving the material of the emitting material layer in the benzene solvent, the xylene solvent, the chlorobenzene solvent or the chloroform solvent;
disposing the benzene solution, the dimethyl solution, the chlorobenzene solution or the chloroform solution on the hole injection layer to form the emitting material layer;
after the step of forming the emitting material layer on the hole injection layer by the second solution further comprising the step of:
forming the alkane-based solution by dissolving the material of the hole blocking layer in the alkane-based solvent;
disposing the alkane-based solution on the emitting material layer to form the hole blocking layer;
the step of forming the electron transport layer on the emitting material layer by the third solution comprising:
forming the aqueous solution or the alcohol solution by dissolving the material of the electron transport layer by the aqueous solvent or the alcohol solvent; and
disposing the aqueous solution or the alcohol solution the hole blocking layer to form the electron transport layer.

12. The method of fabricating of the organic light emitting device according to claim 7, wherein the material of the hole injection layer is a PEDOT: PSS material, the material of the electron transport layer is the first non-polar type solvent-soluble organic material, and the material of the emitting material layer is the second non-polar type solvent-soluble organic material, wherein the first non-polar type solvent comprising the alkane-based solvent, the second non-polar type solvent comprising the benzene solvent, the xylene solvent, the chlorobenzene solvent and the chloroform solvent;
the step of forming the hole injection layer on the anode layer by the first solution comprising:
forming the PEDOT: PSS solution by dissolving the PEDOT: PSS material by aqueous solvent;
disposing the PEDOT: PSS solution on the anode layer to form the hole injection layer;
the step of forming the emitting material layer on the hole injection layer by the second solution comprising:
forming the benzene solution, the dimethyl solution, the chlorobenzene solution or the chloroform solution by dissolving the material of the emitting material layer in the benzene solvent, the xylene solvent, the chlorobenzene solvent or the chloroform solvent;
disposing the benzene solution, the dimethyl solution, the chlorobenzene solution or the chloroform solution on the hole injection layer to form the emitting material layer;
the step of forming the electron transport layer on the emitting material layer by the third solution comprising:
forming the alkane-based solution by dissolving the material of the electron transport layer by the alkane-based solvent; and
disposing the alkane-based solution the emitting material layer to form the electron transport layer.

13. An organic light emitting device, comprising:
a substrate;
an anode layer disposed on the substrate;
a hole injection layer disposed on the anode layer, wherein the hole injection layer is formed by a first solution;
an emitting material layer disposed on the hole injection layer, wherein the emitting material layer is formed by a second solution, the hole injection layer is insoluble in the second solution;
an electron transport layer disposed on the emitting material layer, wherein the electron transport layer is formed by the third solution, the emitting material layer is insoluble in the third solution; and
a cathode layer disposed on the electron transport layer.

14. The organic light emitting device according to claim 13, wherein the material of the hole injection layer is a PEDOT: PSS material, the material of the emitting material layer is the first non-polar type solvent-soluble organic material, and the material of the electron transport layer is a polar type solvent-soluble organic material; and
wherein the first non-polar type solvent comprising an alkane-based solvent, the polar type solvent comprising an aqueous solvent or an alcohol solvent.

15. The organic light emitting device according to claim 13, wherein the organic light emitting device further comprising an electron blocking layer, the material of the electron blocking layer is a second non-polar type solvent-soluble organic material, wherein, the second non-polar type solvent comprising a benzene solvent, a xylene solvent, a chlorobenzene solvent and a chloroform solvent.

16. The organic light emitting device according to claim 13, wherein the organic light emitting device further comprising a hole transport layer, the material of the hole transport layer is the second non-polar type solvent-soluble organic material, wherein, the second non-polar type solvent comprising the benzene solvent, the xylene solvent, the chlorobenzene solvent and the chloroform solvent.

17. The organic light emitting device according to claim 13, wherein the organic light emitting device further comprising a hole blocking layer, the material of the hole blocking layer is the first non-polar type solvent-soluble organic materials;
the material of the hole injection layer is the PEDOT: PSS material, the material of the emitting material layer is the second non-polar type solvent-soluble organic material, the material of the electron transport layer is a polar type solvent-soluble organic material; and
wherein the wherein the first non-polar type solvent comprising an alkane-based solvent, the second non-polar type solvent comprising the benzene solvent, the xylene solvent, the chlorobenzene solvent and the chloroform solvent and the polar type solvent comprising an aqueous solvent or an alcohol solvent.

18. The organic light emitting device according to claim 14, wherein the material of the hole injection layer is a PEDOT: PSS material, the material of the electron transport layer is the first non-polar type solvent-soluble organic material, and the material of the emitting material layer is a second non-polar type solvent-soluble organic material; and
wherein the first non-polar type solvent comprising an alkane-based solvent, the second non-polar type solvent comprising the benzene solvent, the xylene solvent, the chlorobenzene solvent and the chloroform solvent and the polar type solvent comprising an aqueous solvent or an alcohol solvent.
